(19) United States
(12) Patent Application Publication
(10) Pub. No.: US 2026/0068599 A1
(43) Pub. Date: Mar. 5, 2026

(54) PROTECTIVE COATING FOR A USED SEMICONDUCTOR PROCESSING COMPONENT

(71) Applicant: MOMENTIVE PERFORMANCE MATERIALS QUARTZ, INC., Strongsville, OH (US)

(72) Inventors: JEFFREY WALTER LENNARTZ, CLEVELAND, OH (US); WEI FAN, BRECKSVILLE, OH (US); JON RUSSELL LEIST, NORTH OLMSTED, OH (US)

(21) Appl. No.: 19/294,537

(22) Filed: Aug. 8, 2025

Related U.S. Application Data
(60) Provisional application No. 63/690,429, filed on Sep. 4, 2024.

(51) Int. Cl. H01L 21/687

(52) U.S. Cl. CPC H01L 21/68757

(57) ABSTRACT

A refurbishment method is provided to restore and protect a semiconductor processing component used in a semiconductor reactor. The method includes removing parasitic deposits from a semiconductor processing component accumulated from the semiconductor reactor. A new protective coating is then applied to the semiconductor processing component.

### RELATED APPLICATIONS

This application claims the benefit of and priority to U.S. Provisional Application No. 63/690,429 filed on Sep. 4, 2024, which is incorporated herein by reference in its entirety.

### TECHNICAL FIELD

In general, the present disclosure relates to a protective coating for a semiconductor processing component, where the protective coating enables effective cleaning and, thus, reuse of the semiconductor processing component. In particular, the disclosure relates to a surface preparation operation for removing a parasitic coating from the semiconductor processing component to expose a surface of the semiconductor processing component suitable for bonding to a new protective coating; and a restorative coating operation for applying the new protective coating on the surface of the semiconductor processing component.

### BACKGROUND OF THE INVENTION

In semiconductor processing, wafer holders and related hardware in semiconductor deposition chambers are commonly made of graphite substrates with protective coatings. The protective coating surface often accumulates other coatings incidental to what the wafers receive. These so-called “fugitive” or “parasitic” coatings eventually become thick enough to distort the components or alter critical dimensions, resulting in the component's removal from service.

### SUMMARY OF THE INVENTION

The following presents a summary of this disclosure to provide a basic understanding of some aspects. This summary is intended to neither identify key or critical elements nor define any limitations of embodiments or claims. Furthermore, this summary may provide a simplified overview of some aspects that may be described in greater detail in other portions of this disclosure.

In one aspect, a refurbishment process is provided that restores a used component having little or no value into a restored component providing qualities and functionality of an original component. The refurbishment process includes a surface preparation step and a restorative coating operation. The used component undergoes surface preparation prior to receiving a new protective coating. The surface preparation includes removal of parasitic coatings, surface cleaning, and/or surface roughening. With a prepared surface, the new protective coating is applied via a restorative coating operation. The used component may include a substrate and an original protective coating on the substrate. The restorative coating operation may be similar to a process utilized to apply the original protective coating. During the restorative coating operation, a new protective coating is applied on the original protective coating and/or on the substrate. Because of the surface preparation, there is substantially no interface or discontinuity between the original protective coating and the new protective coating. Thus, the restored component includes the substrate and a restored protective coating on the substrate, where the restored protective coating includes the original protective coating and the new protective coating.

These and other aspects will be evident when viewed in light of the drawings, detailed description, and appended claims.

### BRIEF DESCRIPTION OF THE DRAWINGS

Various non-limiting embodiments may take physical form in certain parts and arrangements of parts, which will be described in detail in the specification and illustrated in the accompanying drawings which form a part hereof, and wherein:

FIG. 1 illustrates a semiconductor processing component with a parasitic coating according to an aspect.

FIG. 2 illustrates a semiconductor processing component after performing the disclosed refurbishment process to restore its original surface qualities according to an aspect.

FIGS. 3 and 4 depict cross-sectional views of exemplary used semiconductor processing components after use in a semiconductor reactor and comprising a parasitic coating according to various aspects.

FIG. 5 illustrates a flow chart of an exemplary, non-limiting method for refurbishing a used semiconductor processing component according to one or more aspects.

FIGS. 6A and 6B illustrate cross-sectional views of exemplary used semiconductor processing components comprising a parasitic coating prior to undergoing the disclosed refurbishment process.

FIG. 6C illustrates a scanning electron microscopy (SEM) image that may correspond to a cross-section of the exemplary used processing components of FIGS. 6A and 6B.

FIGS. 7A and 7B illustrate cross-sectional views of exemplary semiconductor processing components after a surface preparation operation that removes the parasitic coating.

FIG. 7C illustrates a SEM image that may correspond to a cross-section of the exemplary semiconductor processing components of FIGS. 7A and 7B comprising the cleaned, original protective coating without the parasitic coating.

FIGS. 8A and 8B illustrate cross-sectional views of exemplary semiconductor processing components after a restorative coating operation is performed to apply a new protective coating to the original protective coating, thereby forming a restored protective coating.

FIG. 8C illustrates a SEM image that may correspond to a cross-section of the exemplary semiconductor processing components of FIGS. 8A and 8B comprising the restored protective coating.

FIGS. 9 and 10 depict chemical profiles for a restored semiconductor processing component.

FIGS. 11A, 11B, 12A, and 12B illustrate various cross-sectional views of a restored semiconductor processing component after a surface preparation operation and a restorative coating operation.

FIGS. 13A and 13B illustrate top-views of the protective coating after a surface preparation operation and after a restorative coating operation, respectively.

FIG. 14 depicts a surface of a cleaned semiconductor processing component according to various aspects.

FIG. 15 provides a graph depicting the flatness of a semiconductor processing component with an original protective coating, with a parasitic coating on the original protective coating, and with a restored protective coating.

### DETAILED DESCRIPTION OF THE INVENTION

As described above, semiconductor processing components used in semiconductor deposition chambers accumulate parasitic coatings, which can distort the components, alter critical dimensions, or otherwise impede the functionality of the components. Other operations on the used parts, such as the partial or complete removal of parasitic coatings, can further impact or degrade the quality and utility of the original protective coating surface and the overall piece of hardware.

Removing parasitic coatings from the base or original protective coating provides a way to extend component lifetime and reduce a user's cost of ownership. A suitable surface preparation operation combined with a suitable original protective base coating will re-expose the original protective base coating, leaving its surface contaminant-free, undamaged, and in a condition that facilitates a pure, well-bonded new protective coating that restores the original surface condition of the protective coating. Application of a new protective coating can be an attractive means to recover used hardware that would otherwise be disposed of or retired. Recoating can significantly extend part life and lower the user's cost of ownership. Coating surfaces before they are properly cleaned will lack these traits and offer less, if any, value to the user.

According to an aspect, a suitably cleaned protective coating is free of all parasitic deposits and undesirable deposit constituents. The cleaned protective coating, while undamaged, exhibits a certain terraced morphology. This feature enables a strongly adhered new protective coating that is restorative to the original protective coating. Together, the new protective coating and the original protective coating form a restored protective coating after the disclosed refurbishment process.

To apply the new protective coating to the prepared surface of the original protective coating, a coating operation like the one used to apply the original protective coating can be used. The original and new protective coatings exhibit substantially no interface or discontinuity between them (e.g., physical, mechanical, chemical) that cause the restored protective coating to perform differently than the original protective coating. The new protective coating exhibits a smooth surface morphology having a structure, purity, grain size, color, and emissivity like that of the original protective coating. The surface preparation and restorative coating operations may be performed sequentially in a single furnace run or in two separate furnace runs. For example, in some embodiments, the surface preparation is performed in a first processing chamber, and the restorative coating operation is performed in a second processing chamber.

To receive a new protective coating of suitable quality (e.g., well-bonded, pure, hermetic), a used piece of semiconductor hardware typically needs surface preparation, details of which may be specific to that hardware and the intended coating operation. Preparation may include removal of parasitic coatings, surface cleaning (e.g., mechanical, chemical, thermal), or surface roughening. With a suitably prepared surface, application of the new protective coating can be performed using the appropriate technology. Because the new protective coating and conditions of application are substantially similar if not identical to the original protective coating and conditions, then compatibility issues that might impair a successful recoating process are minimal.

If the new protective coating is intended for a surface which had no original protective coating material, or the original protective coating's composition or deposition process is substantially different than that of the new protective coating, then it is critical that properties of the substrate, the original protective coating (if present), and the new protective coating are sufficiently understood to ensure good compatibility between the new protective coating and the substrate and/or between the new protective coating and the original protective coating. In some instances, before the new protective coating is applied, surfaces of the substrate are exposed. In some such instances, it is critical that properties of the substrate, the original protective coating, and the new protective coating are sufficiently understood. Substrate and protective coating properties to consider for compatibility would include coefficient of thermal expansion (CTE), density, surface morphology, roughness, porosity, grain size, anisotropy of properties, and interface chemistry and reactions. Also to consider for successful new protective coating application and eventual hardware performance are the temperature of restorative coating operation and the hardware service temperature, with particularly attention paid to the stress state of the new protective coating during formation and use, and the thermomechanical behavior that might drive tensile or compressive failure of the restored protective coating or bond between the original and new protective coatings and/or between the substrate and the new protective coating.

The techniques described herein provide a low-cost refurbished semiconductor processing component with a long usable life. The semiconductor processing component may include a protective coating over a substrate. The substrate may include graphite, silicon carbide, and/or some other suitable material for its intended use. The protective coating includes a suitable composition that can withstand high temperatures and/or gases and chemicals used during semiconductor processing. In some embodiments, for example, the protective coating includes tantalum carbide (TaC). The protective coating may include more than one layer. For example, in some embodiments, the substrate includes graphite; a first protective coating layer comprising silicon carbide is arranged on the substrate; and a second protective coating layer comprising tantalum carbide is arranged on the first protective coating layer. In some such embodiments, at least the second protective coating layer is exposed during the surface preparation operation. In some embodiments, the surface preparation operation includes a high-temperature cleaning process to remove parasitic coatings and undesirable deposit constituents. The original base protective coating, which preferably includes a suitable composition (e.g., a tantalum carbide (TaC) coating), may be restored with a new protective coating. Some pieces of semiconductor hardware have outermost protective base coatings (e.g., a silicon carbide (SiC) coating) which may not be as readily restored via the cleaning process described herein.

With reference to the drawings, like reference numerals designate identical or corresponding parts throughout the several views. The inclusion of like elements in different views, however, does not mean a given embodiment necessarily includes such elements or that all embodiments include such elements. The examples and figures are illustrative only and not meant to be limiting of the claimed subject matter.

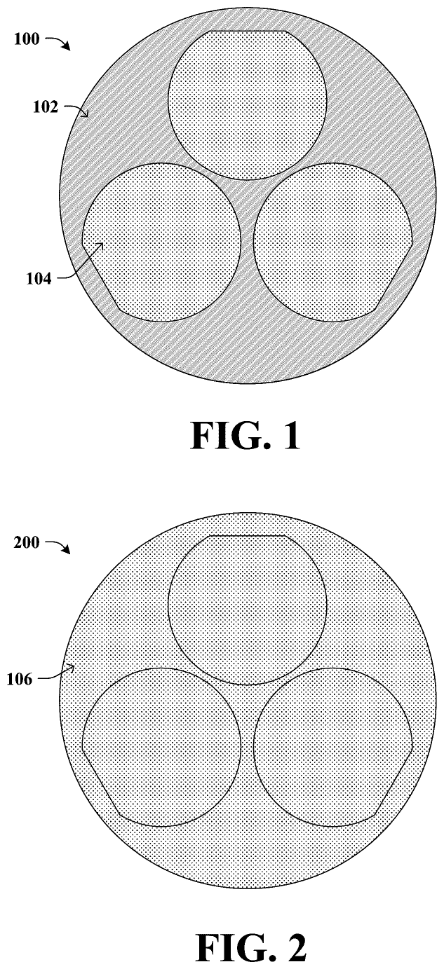

Turning now to FIG. 1, a top view of a used semiconductor processing component 100 is depicted. In particular, the used semiconductor processing component 100 in FIG. 1 is a wafer holder or carrier. As shown in FIG. 1, some portions of the component 100 have a parasitic coating 102, which accumulated through use of the component 100 in a semiconductor deposition chamber. In some applications, the “parasitic coating” may also be referred to as a “parasitic deposit,” a “fugitive coating,” or a “fugitive deposit.” As seen in FIG. 1, locations where semiconductor wafers are placed show little to no parasitic coating. At such locations, an original protective coating 104 may be visible. In some examples, the parasitic coating 102 may be silicon carbide (SIC). The original protective coating 104 may include TaC. In some other embodiments, if the used semiconductor processing component 100 did not originally include a protective coating, then at the locations where semiconductor wafers are placed in the component 100 which include little to no parasitic coating, the material of the underlying substrate may be visible. The parasitic coating 102 may have a varying thickness throughout the component 100 and may not cover the entire component 100.

FIG. 2 depicts a restored component 200 corresponding to the used component 100 of FIG. 1 after undergoing the surface preparation and restorative coating operations of the refurbishment process described herein. After the refurbishment process, the entirety of the component 100 includes a restored protective coating 106. In some embodiments, the restored protective coating 106 includes a same material as the original protective coating 104. In other embodiments, the restored protective coating 106 includes a different material than but still compatible with that of the original protective coating 104.

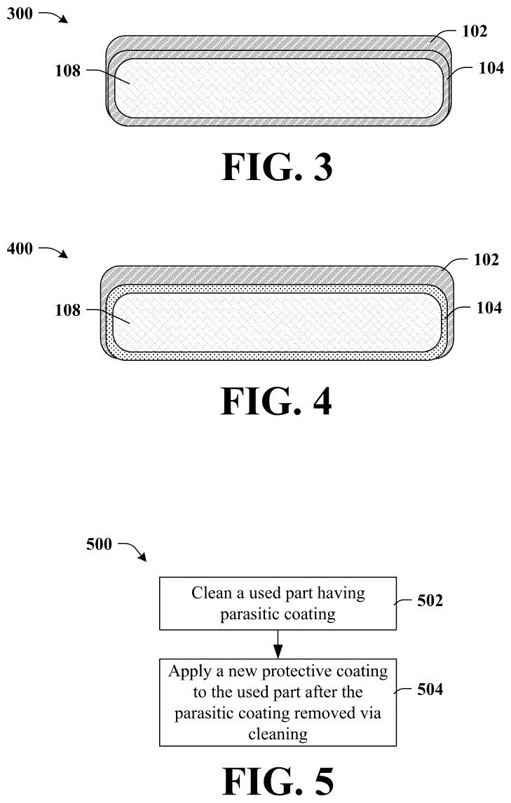

FIG. 3 depicts a cross-sectional view of a used component 300 according to one example. Component 300 may have a substrate 108 comprising graphite with an original protective coating 104 comprising SiC. In an example, the SiC coating 104 may have a thickness of approximately 80 to 100 micrometers. Through use of the component 300 in SiC deposition chambers, the component 300 accumulates a parasitic coating 102 comprising SiC, which may have a thickness of approximately 400 to 500 micrometers. In some embodiments, depending on the location of the component 300 within a deposition chamber, only some portions of the original protective coating 104 are covered by the parasitic coating 102. In some other embodiments, after several uses in the deposition chamber, substantially all (e.g., more than 95% of the surface area) of the originally protective coating 104 is covered by the parasitic coating 102.

FIG. 4 depicts a cross-section of a used component 400 according to another example. Component 400 may have a substrate 108 comprising graphite provided with an original protective coating 104 comprising TaC. The TaC original protective coating 104 may have a thickness of approximately 20 to approximately 60 micrometers or more preferably approximately 35 to approximately 40 micrometers. Through use, the component 400 accumulates a parasitic coating 102 of SiC, which may have a thickness of approximately 300 to 400 micrometers.

According to one aspect, the used semiconductor processing component (e.g., 300, 400) are utilized in a semiconductor reactor and can be cleaned by removing parasitic deposits and subsequently recoated with a new protective coating to restore original properties. The semiconductor processing component (e.g., 300, 400) may be a wafer handling apparatus, a support component, a shower head, a heat shield, an inlet or outlet, for example. The component includes a certain class of protective coating 104 that is substantially resistant to the surface preparation operation. Accordingly, the cleaning process removes parasitic coating 102, but not any or at least not a significant amount of the original protective coating 104. According to an example, the parasitic coating 102 may be silicon, germanium, gallium nitride, aluminum nitride, gallium arsenide, indium phosphide, silicon carbide, gallium oxide, silicon oxide, silicon nitride, and any free form of gallium, aluminum, indium, carbon, combinations therefor, or multiple layers of one or more of the foregoing. According to various examples, the original protective coating 104 may include tantalum carbide, niobium carbide, zirconium carbide, hafnium carbide, tungsten carbide, molybdenum carbide, combinations thereof, or multiples layers of one or more of the foregoing. In general, the original protective coating 104 has a higher chemical and thermal stability than the parasitic coating 102 and also can have a higher chemical and thermal stability than the underlying substrate 108, thereby protecting the underlying substrate 108 during semiconductor processing methods. The original protective coating 104 exhibits a microscopic smooth surface morphology with an average surface roughness from approximately 0.2 to 2 micrometers and a grain size ranging from approximately 5 to 50 micrometers.

As will be discussed further herein, after a surface preparation operation, the cleaned, original protective coating is free of silicon, germanium, gallium nitride, aluminum nitride, gallium arsenide, indium phosphide, silicon carbide, gallium oxide, silicon oxide, silicon nitride, and any free form of gallium, aluminum, indium, phosphorous, silicon, germanium, and carbon. After the surface preparation operation, the cleaned, original protective coating exhibits a microscopic terrace surface morphology with step density ranging from approximately 0.1 to 2 per micrometer. After the surface preparation operation, the cleaned, original protective coating also exhibits microscopic sub-grain boundaries with a density ranging from approximately 1 to 10 per grain. The microscopic terraces of the cleaned, original protective coating function as nucleation sites to continue growth of a new protective coating growth during a restorative coating operation and, thus, eliminate any interface between the original base protective coating and the new protective coating.

FIG. 5 illustrates a flow chart of an exemplary method 500 for refurbishing a used semiconductor processing component. At 502, a used part having a parasitic coating is cleaned by way of a surface preparation operation. At 504, a new protective coating is applied to the used part by way of a restorative coating operation after the parasitic coating is removed. According to an example, steps 502 and 504 may be performed as two steps in a single furnace run. In another example, steps 502 and 504 are performed in two separate furnace runs.

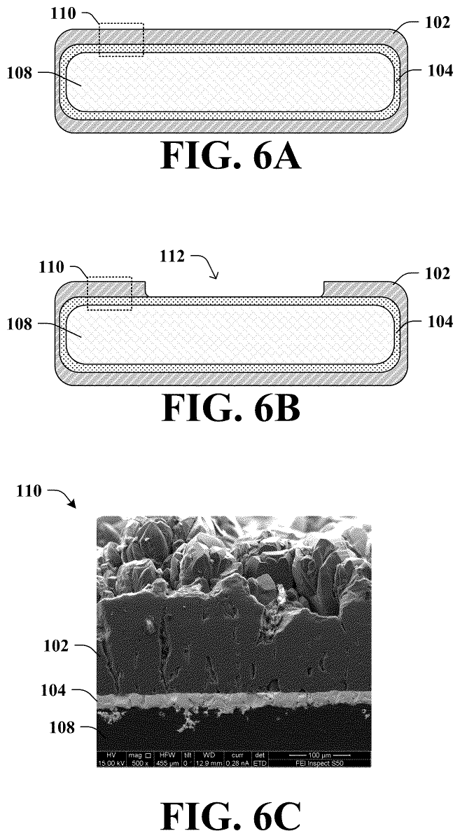

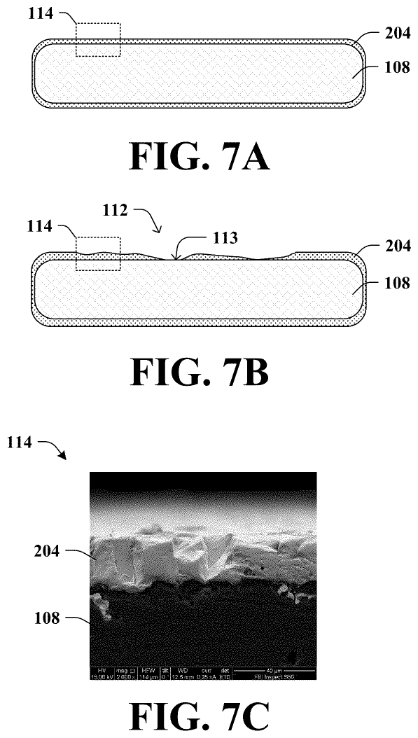

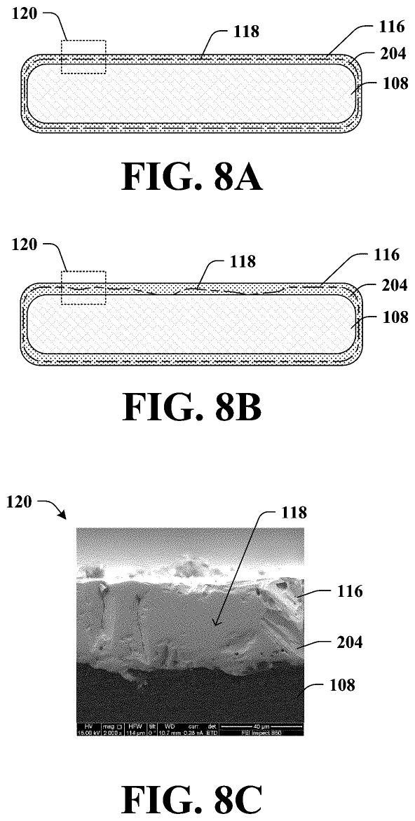

The method of FIG. 5 will be further described with respect to FIGS. 6A, 6B, 6C, 7A, 7B, 7C, 8A, 8B, and 8C. FIGS. 6A-6C provide exemplary views of a used semiconductor processing component prior to the refurbishment process; FIGS. 7A-7C provide exemplary views of the used semiconductor processing component after the surface preparation operation of step 502; and FIGS. 8A-8C provide exemplary views of the used semiconductor processing component after the restorative coating operation of step 504.

Turning now to FIGS. 6A, 6B, and 6C various embodiments of a used semiconductor processing component are shown, which have a thick parasitic coating 102 that should be removed or else the component would have to be discarded. In an embodiment, the substrate 108 is graphite, the thick parasitic coating 102 is SiC, and the original protective coating 104 is TaC. As shown in FIG. 6A, the parasitic coating 102 may fully surround the substrate 108. As shown in FIG. 6B, in some embodiments, the used semiconductor processing component has areas 112 that do not include the parasitic coating 102. Such areas 112 may have been covered by other chamber components or semiconductor wafers during the semiconductor processing such that the original protective coating 104 was not exposed during deposition processes. It will be appreciated that the “original” protective coating 104 could be the true, original protective coating that was applied to the substrate 108 before the component was ever in-use or the “original” protective coating 104 could be a previously restored protective coating; in either instance, the “original” protective coating 104 is the protective coating 104 on the substrate 108 before accumulating this particular parasitic coating 102.

A magnified cross-sectional view 110 of the substrate 108, the original protective coating 104, and the parasitic coating 102 is provided in FIG. 6C. The magnified view 110 of FIG. 6C is a scanning electron microscopy (SEM) image and may correspond to the boxes 110 in FIGS. 6A and 6B. As shown in FIG. 6C, the parasitic coating 102 may be significantly thicker than the underlying original protective coating 104. As an example, the parasitic coating 102 may be at least two times as thick as the original protective coating 104 or even at least four times as thick as the original protective coating 104. In some embodiments, the upper surface of the substrate 108 is not completely smooth due to machining of the substrate 108. As seen in FIG. 6C, the original protective coating 104 can fill in any defects on the upper surface of the substrate 108 and have a more planar upper surface compared to that of the substrate 108. The parasitic coating 102 may have a varying thickness and surface roughness on the original protective coating 104.

The used semiconductor processing components of FIGS. 6A, 6B, and 6C may undergo a surface preparation operation to remove the parasitic coating 102. The surface preparation operation can include a removal process and a surface treatment process. For example, the parasitic coating 102 may be removed via mechanical and/or chemical removal processes to expose the original protective coating 104. A surface treatment process may then be performed to prepare the original protective coating 104 for receiving and bonding to a future new protective coating. In some embodiments, the removal process is sufficient in also functioning as a surface treatment process, while in other embodiments, the surface treatment process is a different method than the removal process. The surface treatment process may adjust the surface roughness of the original protective coating 104 and remove any remaining residue from the removal process.

Turning now to FIGS. 7A, 7B, and 7C, the cleaned component is shown after the surface preparation operation is performed. FIGS. 7A, 7B, and 7C may correspond to FIGS. 6A, 6B, and 6C, respectively. The original protective coating 104 of FIGS. 6A, 6B, and 6C is labeled as a cleaned, original protective coating 204 in FIGS. 7A, 7B, and 7C to indicate that the surface preparation operation has been performed. The cleaned, original protective coating 204 may have a different surface roughness and a different thickness than the original protective coating 104. As shown in FIG. 7B, for example, at the area 112 of the cleaned component that did not include a parasitic coating 102, the cleaned, original protective coating 204 may have a reduced thickness and/or an increased surface roughness for being exposed to the surface preparation operation longer than other areas of the cleaned, original protective coating 204. In some embodiments, some upper surfaces 113 of the substrate 108 are exposed during the surface preparation operation.

A magnified cross-sectional view 114 of the substrate 108, the cleaned, original protective coating 204 is provided in FIG. 7C. The magnified view 114 of FIG. 7C is an SEM image and may correspond to the boxes 114 in FIGS. 7A and 7B. As shown in FIG. 7C, the cleaned, original protective coating 204 may have various surface defects from the surface preparation operation. In an example, the cleaned, original protective coating 204 may have an average thickness of approximately 26 micrometers.

Turning now to FIGS. 8A, 8B, and 8C, the cleaned component is shown as a restored component after a restorative coating operation is performed. FIGS. 8A, 8B, and 8C may correspond to FIGS. 7A, 7B, and 7C, respectively. The restorative coating operation applies a new protective coating 116 to the cleaned, original protective coating 204. The new protective coating 116 may be the same material as the cleaned, original protective coating 204, such as TaC, for example, An interface 118 between the new protective coating 116 and the cleaned, original protective coating 204 is illustrated with a hashed line because there is substantially no interface or discontinuity between the cleaned, original protective coating 204 and the new protective coating 116. As best shown in FIG. 8B, in some embodiments, the new protective coating 116 directly contacts the substrate 108 such that the sealing and protection of the substrate 108 is restored. Together, the cleaned, original protective coating 204 and the new protective coating 116 form a restored protective coating on the substrate 108 such that the restored component may be used again in a semiconductor processing chamber.

As an example, the cleaned, original protective coating 204 may have an average thickness of approximately 26 micrometers and the new protective coating 116 may have an average thickness of approximately 15 micrometers. In some embodiments, the average thickness of the new protective coating 116 is between about 5 micrometers and about 25 micrometers. Thus, in some embodiments, the new protective coating 116 is thinner than the cleaned, original protective coating 204. In other embodiments, such as if a lot of the original protective coating 104 is removed during the surface preparation operation, the new protective coating 116 is thicker than the cleaned, original protective coating 204.

A magnified cross-sectional view 120 of the substrate 108, the cleaned, original protective coating 204, and the new protective coating 116 is provided in FIG. 8C. The magnified view 120 of FIG. 8C is an SEM image and may correspond to the boxes 120 in FIGS. 8A and 8B. As shown in FIG. 8C, there is no visible interface 118 between the cleaned, original protective coating 204 and the new protective coating 116. The restored component therefore does not present a chemical or physical interruption or discontinuity between the cleaned, original protective coating 204 and the new protective coating 116. Additionally, in some embodiments, the restored protective coating, which has a topmost surface defined by the new protective coating 116 shown in FIG. 8C, may have a lower surface roughness compared to the topmost surface of the cleaned, original protective coating 204 shown in FIG. 7C.

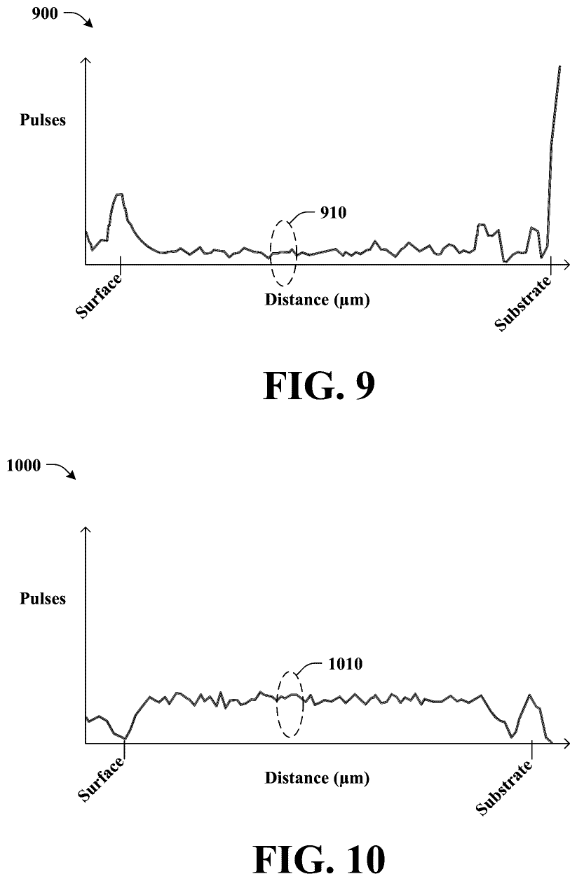

Turning now to FIGS. 9 and 10, energy-dispersive X-ray spectroscopy (EDS) depth profiles are shown for a restored semiconductor processing component comprising the restored protective coating comprising carbon and tantalum. Profile 900 of FIG. 9 corresponds to carbon intensity, and profile 1000 of FIG. 10 corresponds to tantalum intensity. In the profiles, the distance closer to 0 corresponds to the surface of the restored protective coating, and the maximum distance depicted corresponds to the surface of the graphite substrate. The distance between the substrate and the surface therefore represents the thickness of the restored protective coating. The interface between the cleaned, original protective coating and the new protective coating is identified (circled) on the profiles at 910 and 1010. As evidence by the EDS depth profiles 900 and 1000, no chemical interruption in carbon or tantalum is present between the cleaned, original protective coating and the new protective coating.

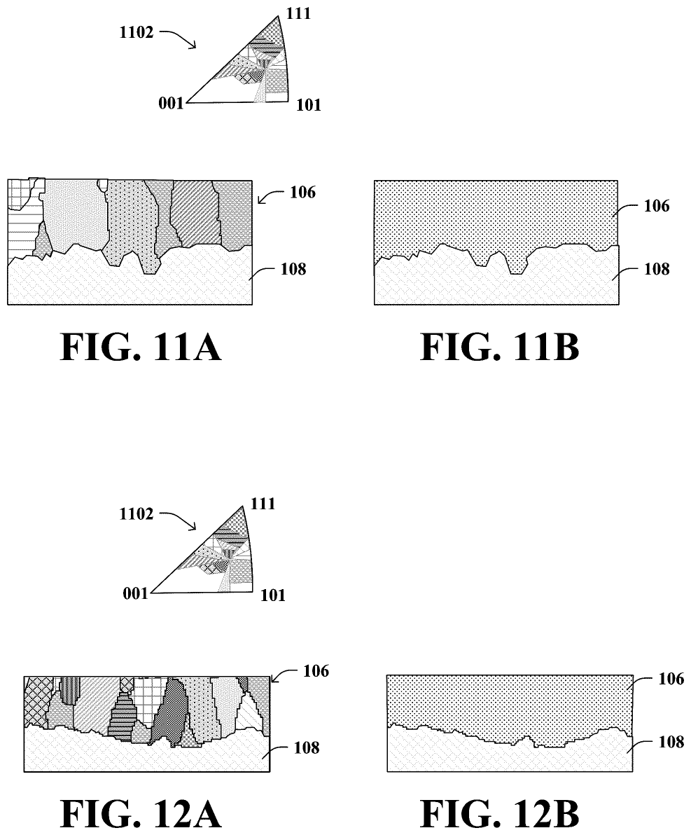

Turning now to FIG. 11A, a schematic of an electron backscatter diffraction (EBSD) image of a first cross-section of the restored component is provided to show the grain structure of the restored protective coating 106 after the surface preparation operation and after the restorative coating operation. A crystal structure key 1102 is provided in FIG. 11A. It will be appreciated that EBSD images and crystal structure keys are typically in colored gradients, but for the purposes of this application, are illustrated in black and white line drawings. FIG. 11B provides a schematic of an SEM image of the same, first cross-section shown in FIG. 11A. Turning additionally to FIG. 12A, a schematic of an EBSD image of a second cross-section of the restored component is provided to show the grain structure of a restored protective coating 106 after the restorative coating operation. FIG. 12B provides a schematic of an SEM image of the same, second cross-section shown in FIG. 12A.

Both the first and second cross-sections are shown in FIGS. 11A and 12A to illustrate that depending on the exact cross-section cut, the grain structure of the restored protective coating 106 may look slightly different; this is at least because the grains extend in three-dimensions but the cross-sections are two-dimensional. For example, in FIG. 11A, most grains in the restored protective coating 106 clearly have a continuous columnar structure and thus, extend from the top surface of the substrate 108 to the top surface of the restored protective coating 106. In some embodiments, preferably more than 50%, more preferably more than 70%, or even more preferably more than 90% of the grains within the restored protective coating 106 have this continuous columnar grain structure. It will be appreciated that the grains of the restored protective coating 106 may extend in three dimensions. Therefore, while less of the grains in FIG. 12A appear to have the continuous columnar structure, the cross-section is two-dimensional and many of the stacked-looking grains still originate from the substrate 108 at an area on the substrate 108 that is into or out of the page, which may be evident when a different cross-section is captured. Thus, even in FIG. 12A, preferably more than 50%, more preferably more than 70%, or even more preferably more than 90% of the grains within the restored protective coating 106 have this continuous columnar grain structure.

It will be appreciated that the term “continuous” does not require all grains to extend from the substrate 108 to a topmost surface of the restored protective coating 106. The grains of the restored protective coating 106 may have different heights throughout the restored protective coating 106 because of the uneven top surface of the substrate 108 and/or because of various processing conditions that effect grain growth. The term “continuous” is instead intended to describe that the majority of the grains of the restored protective coating 106 still nucleate from the substrate 108 instead of from other grains of the restored protective coating 106.

The original protective coating may also have a continuous columnar grain structure. Therefore, during deposition of the new protective coating, the grains of the cleaned, original protective coating grow to form the restored protective coating 106 instead of forming new nucleation sites on the grains of the cleaned, original protective coating. At some areas where the substrate 108 is exposed, grains of the new protective coating may nucleate at such exposed areas of the substrate 108. With the substantially same crystal structure as the original protective coating and with substantially no interruption in crystal structure between the cleaned, original protective coating and the new protective coating, the resulting restored protective coating 106 has substantially the same properties as the original protective coating prior to accumulating any parasitic deposits.

In some other embodiments, the restored protective coating 106 does have a grain structure where more than 10% of the grains formed during the deposition of the new protective coating nucleate from grains in the cleaned, original protective coating. In some such other embodiments, the grain structure may have some continuous columnar grains and may also have some “stacked” columnar grains. The stacked columnar grains may be formed if the new protective coating comprises a different material than the original protective coating and/or contains some impurities. The stacked columnar grains may also be formed if a different deposition process is used to form the new protective coating than that of the original protective coating. In some embodiments, adjusting the parameters (e.g., time, temperature, pressure) of the deposition process for the new protective coating may also result in some more stacked columnar grains.

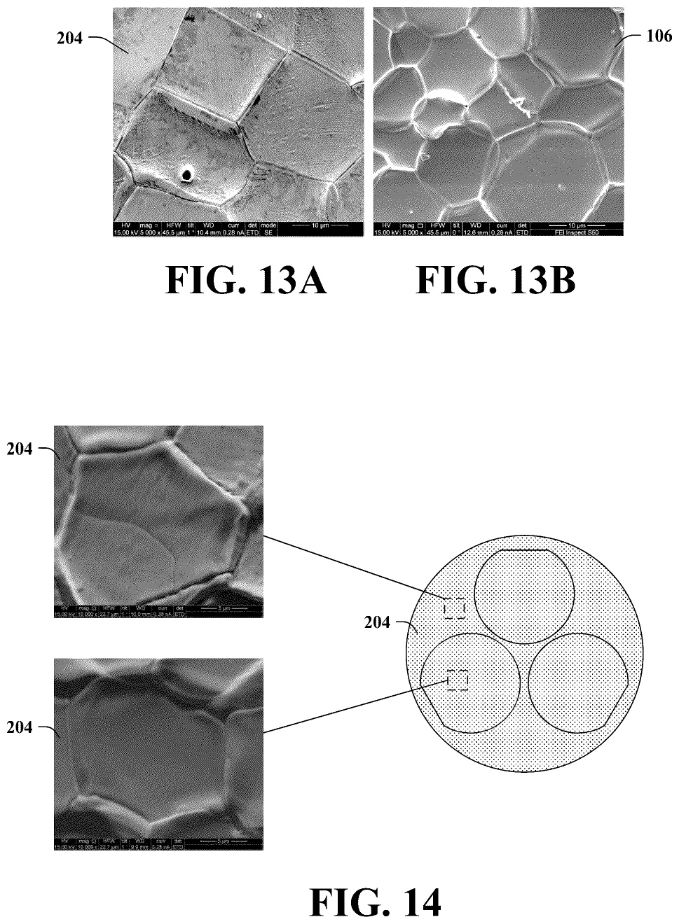

FIGS. 13A and 13B depict SEM images of a top surface of the various protective coatings. FIG. 13A provides the SEM image of a top surface of some embodiments of the cleaned, original protective coating 204 having a finely terraced surface morphology. In some embodiments, the terraced morphology has a step density ranging from approximate 0.1 to 2 per micrometer. FIG. 13B provides the SEM image of a top surface of some embodiments of the restored protective coating 106, where the surface qualities of an original TaC protective coating (e.g., 104) are restored.

FIG. 14 depicts TaC surfaces of the cleaned, original protective coating 204 at a location on the cleaned semiconductor processing component where a SiC parasitic coating 102 accumulated and a location where no SiC parasitic coating was present. In both locations, the surface preparation operation was performed. The upper SEM image of FIG. 14 corresponds to a location where a parasitic coating 102 was cleaned and shows a new sub-grain boundary. In some embodiments, the sub-grain boundary density ranges from approximately 1 to 10 sub-grain boundaries per grain. The lower SEM image of FIG. 14 corresponds to a location without a parasitic coating and does not show any sub-grain boundary. The sub-grain boundaries formed from the surface preparation operation shown in FIG. 14 can provide nucleation sites for growth of the new protective coating 116 and are no longer present after the new protective coating 116 is deposited on the cleaned, original protective coating 204, as shown in FIG. 13B. Thus, the restorative coating process substantially “heals” the cleaned, original protective coating 204 such that the resulting restored protective coating 106 behaves similarly to the original protective coating 104 prior to any parasitic coating accumulation. In some embodiments of FIG. 13B, the restored protective coating 106 exhibits a microscopically smooth grain surface morphology without a terrace structure and with a roughness of approximately 0.2 to 2 micrometers and grain size ranging from approximately 5 to 50 micrometers.

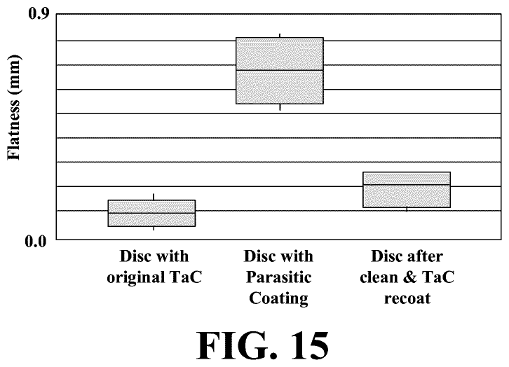

FIG. 15 depicts a flatness comparison plot between semiconductor processing components with their original TaC coating (104), used semiconductor processing components having a SiC parasitic coating (102), and refurbished semiconductor processing components having a restored protective coating (106) after cleaning and recoating. The parts, in this example, are disc-shaped wafer carriers with a diameter of approximately 340 mm. In some embodiments, although complete restoration of the original disc flatness may not be achieved, the disclosed refurbishment process may improve flatness of the semiconductor process component by approximately 50 to 80% compared to the uncleaned part. Some flatness measurements of the disc with original TaC before use and the disc after the refurbishment process do overlap with one another.

According to another example, a refurbishment process is provided that removes parasitic deposits and applies a protective coating to a semiconductor processing component, such as a wafer holder component, that has been used in a semiconductor reactor. The new protective coating heals any defects, pin holes, scratches, and deformation in the original protective coating and/or the underlying substrate. According to an example, the parasitic deposits may include silicon, germanium, gallium nitride, aluminum nitride, gallium arsenide, indium phosphide, silicon carbide, gallium oxide, silicon oxide, silicon nitride, any free form of gallium, aluminum, indium, carbon, combinations therefor, or multiple layers of one or more of the foregoing. The surface preparation operation which removes the parasitic deposits exploits differences in high temperature behavior between parasitic deposits and the component.

The semiconductor processing component may include an original protective coating. In other examples, the semiconductor processing component does not include an original protective coating. The component may include graphite, a carbon fiber composite, other carbon-based materials, combinations thereof, or multiple layers of one more of the foregoing.

In an example, the original protective coating and the restored protective coating applied withstand the service environment of the semiconductor processing component. In another example, the original and restored protective coatings withstand exposure to silicon-, nitrogen-, carbon-, halogen-, and/or hydrogen-containing gas species (e.g., ammonia, hydrogen, silane, and trichlorosilane) at temperatures above 1000° C. In another example, the original and restored protective coatings withstand exposure to silicon-, nitrogen-, carbon-, halogen-, and/or hydrogen-containing gas species (e.g., ammonia, hydrogen, silane, and trichlorosilane) at temperatures above 1600° C. In yet another example, the original and restored protective coatings withstand exposure to silicon-, nitrogen-, carbon-, halogen-, and/or hydrogen-containing gas species (e.g., ammonia, hydrogen, silane, and trichlorosilane) at temperatures above 2000° C.

In an example, the original protective coating also withstands the service environment of the disclosed surface preparation operation. In some embodiments, removal of the parasitic coating during the surface preparation operation is performed by way of chemical or mechanical processes, such as laser removal, sublimation or dissociation at high temperatures, chemical etching, chemical mechanical planarization, surface grinding, some other suitable removal process, or combination thereof. As an example, the used semiconductor processing component may be exposed to various heating steps to remove the parasitic coating and a mechanical brushing process may be used to remove any residual parasitic material.

In an example, the original and restored protective coatings are chemically stable 100° C. above a decomposition temperature of silicon carbide. In another example, the original and restored protective coating are chemically stable 500° C. above a decomposition temperature of silicon carbide. In yet another example, the original and restored protective coatings are chemically stable 1000° C. above a decomposition temperature of silicon carbide.

In another example, the original and/or restored protective coatings are prepared by thermal spray (e.g., plasma spray, SPS, HVOF, detonation gun), vapor deposition (e.g., CVD, PVD, PECVD, ALD), electrochemical deposition, sol-gel, slurry spray or dip, sintering, or the like. The original and/or restored protective coatings may contain metal ceramic, or a combination thereof.

Still further, the original and/or restored protective coating may include tantalum carbide, niobium carbide, zirconium carbide, hafnium carbide, tungsten carbide, molybdenum carbide, combinations thereof, or multiples layers of one or more of the foregoing. The new protective coating may be the same as an original protective coating on the semiconductor processing component. The new protective coating may be different from the original protective coating on the semiconductor processing component.

In a further example, the refurbishment process reduces a stress-induced curvature in the used component by more than 50%. In another example, the cleaning and recoating process reduces a curvature of the used component by more than 75%.

The following are non-limited examples of some embodiment of the present disclosure: Embodiment 1. A method comprising:
removing parasitic deposits from a semiconductor processing component used in a semiconductor reactor; and
applying a new protective coating to the semiconductor processing component.

Embodiment 2. The method of Embodiment 1, wherein the parasitic deposits include one or more layers of one or more of GaN, AlN, GaAs, InP, SiC, SiO₂, Si₃N₄, Ga₂O₃; any free form of Al, In, Si, Ga, C; or combinations thereof.

Embodiment 3. The method of Embodiment 1, wherein the semiconductor processing component includes an original protective coating on a substrate, the parasitic deposits being arranged directly on the original protective coating, wherein the original protective coating is exposed upon removal of the parasitic deposits, and wherein the new protective coating is applied to the original protective coating to form a restored protective coating.

Embodiment 4. The method of Embodiment 3, wherein the new protective coating comprises a same material as the original protective coating.

Embodiment 5. The method of Embodiment 3, wherein after the removal step, the original protective coating has a microscopic terrace surface morphology with step density ranging from approximately 0.1 to 2 per micrometer.

Embodiment 6. The method of Embodiment 3, wherein after the removal step, the original protective coating has microscopic sub-grain boundaries with density ranging from approximately 1 to 10 per grain.

Embodiment 7. The method of Embodiment 6, wherein new protective coating has a top surface that is substantially free of sub-grain boundaries.

Embodiment 8. The method of Embodiment 3, wherein the original protective coating comprises a continuous columnar grain structure comprising columnar grains that extend from a top surface of the substrate to a top surface of the original protective coating.

Embodiment 9. The method of Embodiment 8, wherein the restored protective coating comprises a continuous columnar grain structure comprising columnar grains that extend from a top surface of the substrate to a top surface of the restored protective coating.

Embodiment 10. The method of Embodiment 1, wherein the semiconductor processing component includes a substrate comprising graphite, a carbon-fiber composite, another carbon-based material, or combinations thereof.

Embodiment 11. The method of Embodiment 1, wherein the new protective coating withstands exposure to one or more of silicon-, nitrogen-, carbon-, halogen-, or hydrogen-containing gas species.

Embodiment 12. The method of Embodiment 1, wherein the new protective coating is applied by thermal spray, vapor deposition, electrochemical deposition, sol-gel, slurry spray, or sintering.

Embodiment 13. The method of Embodiment 1, wherein the new protective coating includes at least one metal or ceramic.

Embodiment 14. The method of Embodiment 1, wherein the new protective coating is a metal carbide, and wherein the metal includes one of Ta, Nb, Zr, Hf, Mo, W, or combinations thereof.

Embodiment 15. The method of Embodiment 1, wherein the removal step and the applying of the new protective coating step are performed in two separate furnace runs.

Embodiment 16. The method of Embodiment 1, wherein the removal step and the applying of the new protective coating step are performed sequentially as two steps in a single furnace run.

Embodiment 17. The method of Embodiment 1, wherein the removal step includes mechanical operations, chemical operations, thermal operations, or combinations thereof.

Embodiment 18. A restored semiconductor processing component comprising:
a substrate; and
a restored protective coating formed by:
   removing parasitic deposits from an original protective coating arranged on the substrate; and
   applying a new protective coating to the cleaned, original protective coating such that the restored protective coating comprises the original protective coating and the new protective coating.

Embodiment 19. The restored semiconductor processing component of Embodiment 18, wherein the restored protective coating comprises columnar grains that continuously extend from a top surface of the substrate to a top surface of the restored protective coating.

Embodiment 20. The restored semiconductor processing component of Embodiment 18, wherein the restored protective coating has a microscopic smooth grain surface morphology with an average surface roughness from approximately 0.2 to 2 micrometers and grain size from approximately 5 to 50 micrometers.

The above examples are merely illustrative of several possible embodiments of various aspects of the present invention, wherein equivalent alterations and/or modifications will occur to others skilled in the art upon reading and understanding this specification and the annexed drawings. In particular regard to the various functions performed by the above described components (assemblies, devices, systems, circuits, and the like), the terms (including a reference to a “means”) used to describe such components are intended to correspond, unless otherwise indicated, to any component, such as hardware, software, or combinations thereof, which performs the specified function of the described component (e.g., that is functionally equivalent), even though not structurally equivalent to the disclosed structure which performs the function in the illustrated implementations of the invention. In addition, although a particular feature of the invention may have been disclosed with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising.”

This written description uses examples to disclose the invention, including the best mode, and also to enable one of ordinary skill in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that are not different from the literal language of the claims, or if they include equivalent structural elements with insubstantial differences from the literal language of the claims.

In the specification and claims, reference will be made to a number of terms that have the following meanings. The singular forms “a”, “an” and “the” include plural referents unless the context clearly dictates otherwise. Approximating language, as used herein throughout the specification and claims, may be applied to modify a quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value. Moreover, unless specifically stated otherwise, a use of the terms “first,” “second,” etc., do not denote an order or importance, but rather the terms “first,” “second,” etc., are used to distinguish one element from another.

As used herein, the terms “may” and “may be” indicate a possibility of an occurrence within a set of circumstances; a possession of a specified property, characteristic, or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity cannot occur—this distinction is captured by the terms “may” and “may be.”

The best mode for carrying out the invention has been described for purposes of illustrating the best mode known to the applicant at the time and enable one of ordinary skill in the art to practice the invention, including making and using devices or systems and performing incorporated methods. The examples are illustrative only and not meant to limit the invention, as measured by the scope and merit of the claims. The invention has been described with reference to preferred and alternate embodiments. Obviously, modifications and alterations will occur to others upon the reading and understanding of the specification. It is intended to include all such modifications and alterations insofar as they come within the scope of the appended claims or the equivalents thereof. The patentable scope of the invention is defined by the claims, and may include other examples that occur to one of ordinary skill in the art. Such other examples are intended to be within the scope of the claims if they have structural elements that do not differentiate from the literal language of the claims, or if they include equivalent structural elements with insubstantial differences from the literal language of the claims.

What is claimed is:

1. A method comprising:
removing parasitic deposits from a semiconductor processing component used in a semiconductor reactor; and
applying a new protective coating to the semiconductor processing component.

2. The method of claim 1, wherein the parasitic deposits include one or more layers of one or more of GaN, AlN, GaAs, InP, SiC, SiO₂, Si₃N₄, Ga₂O₃; any free form of Al, In, Si, Ga, C; or combinations thereof.

3. The method of claim 1, wherein the semiconductor processing component includes an original protective coating on a substrate, the parasitic deposits being arranged directly on the original protective coating, wherein the original protective coating is exposed upon removal of the parasitic deposits, and wherein the new protective coating is applied to the original protective coating to form a restored protective coating.

4. The method of claim 3, wherein the new protective coating comprises a same material as the original protective coating.

5. The method of claim 3, wherein after the removal step, the original protective coating has a microscopic terrace surface morphology with step density ranging from approximately 0.1 to 2 per micrometer.

6. The method of claim 3, wherein after the removal step, the original protective coating has microscopic sub-grain boundaries with density ranging from approximately 1 to 10 per grain.

7. The method of claim 6, wherein new protective coating has a top surface that is substantially free of sub-grain boundaries.

8. The method of claim 3, wherein the original protective coating comprises a continuous columnar grain structure comprising columnar grains that extend from a top surface of the substrate to a top surface of the original protective coating.

9. The method of claim 8, wherein the restored protective coating comprises a continuous columnar grain structure comprising columnar grains that extend from a top surface of the substrate to a top surface of the restored protective coating.

10. The method of claim 1, wherein the semiconductor processing component includes a substrate comprising graphite, a carbon-fiber composite, another carbon-based material, or combinations thereof.

11. The method of claim 1, wherein the new protective coating withstands exposure to one or more of silicon-, nitrogen-, carbon-, halogen-, or hydrogen-containing gas species.

12. The method of claim 1, wherein the new protective coating is applied by thermal spray, vapor deposition, electrochemical deposition, sol-gel, slurry spray, or sintering.

13. The method of claim 1, wherein the new protective coating includes at least one metal or ceramic.

14. The method of claim 1, wherein the new protective coating is a metal carbide, and wherein the metal includes one of Ta, Nb, Zr, Hf, Mo, W, or combinations thereof.

15. The method of claim 1, wherein the removal step and the applying of the new protective coating step are performed in two separate furnace runs.

16. The method of claim 1, wherein the removal step and the applying of the new protective coating step are performed sequentially as two steps in a single furnace run.

17. The method of claim 1, wherein the removal step includes mechanical operations, chemical operations, thermal operations, or combinations thereof.

18. A restored semiconductor processing component comprising:
a substrate; and
a restored protective coating formed by:
removing parasitic deposits from an original protective coating arranged on the substrate; and
applying a new protective coating to the cleaned, original protective coating such that the restored protective coating comprises the original protective coating and the new protective coating.

19. The restored semiconductor processing component of claim 18, wherein the restored protective coating comprises columnar grains that continuously extend from a top surface of the substrate to a top surface of the restored protective coating.

20. The restored semiconductor processing component of claim 18, wherein the restored protective coating has a microscopic smooth grain surface morphology with an average surface roughness from approximately 0.2 to 2 micrometers and grain size from approximately 5 to 50 micrometers.
